(19) United States
(12) Patent Application Publication
(10) Pub. No.: US 2026/0206420 A1
(43) Pub. Date: Jul. 16, 2026

(54) DISPLAY PANEL, METHOD OF MANUFACTURING DISPLAY PANEL, AND ELECTRONIC DEVICE INCLUDING DISPLAY PANEL

(71) Applicant: Samsung Display Co., Ltd., Yongin-si (KR)

(72) Inventors: Myounggeun Cha, Yongin-si (KR); Sanggun Choi, Yongin-si (KR); Hanbit Kim, Yongin-si (KR); Thanhtien Nguyen, Yongin-si (KR); Dokyeong Lee, Yongin-si (KR)

(21) Appl. No.: 19/306,859

(22) Filed: Aug. 21, 2025

(30) Foreign Application Priority Data
Jan. 15, 2025 (KR) 10-2025-0006384

(51) Int. Cl. H10K 59/122; H10K 59/12; H10K 59/131

(52) U.S. Cl. CPC H10K 59/122; H10K 59/1201; H10K 59/131

(57) ABSTRACT

A display panel includes: a substrate; a conductive layer on the substrate; a plurality of insulating layers on the conductive layer and having a contact opening overlapping the conductive layer; a semiconductor layer within the plurality of insulating layers, the semiconductor layer having a first portion that protrudes beyond an inner wall of the plurality of insulating layers defining the contact opening to be within the contact opening; and a contact metal on the plurality of insulating layers and extending into the contact opening to contact both the semiconductor layer and the conductive layer.

### CROSS-REFERENCE TO RELATED APPLICATION

The present application claims priority to and the benefit of Korean Patent Application No. 10-2025-0006384, filed on Jan. 15, 2025, in the Korean Intellectual Property Office, the entire disclosure of which is incorporated herein by reference.

### BACKGROUND

### 1 Field

Aspects of embodiments of the present disclosure relate to a display panel, a method of manufacturing a display panel, and an electronic device including a display panel.

### 2. Description of the Related Art

An electronic device may display images or videos by using a display panel provided on the electronic device. The display panel may display data visually. The display panel may provide videos or images by using pixels. Display panels have become more diverse in their uses, and various designs have been attempted to improve the quality of the display panels.

### SUMMARY

A pixel of a display panel may include a light-emitting diode and a pixel circuit connected to the light-emitting diode. The light-emitting diode may be driven through (or by) the pixel circuit. Reducing an area in which light-emitting diodes and pixel circuits are arranged helps provide a high-resolution display panel. For example, to improve the integration of light-emitting diodes and pixel circuits, an area occupied by a single pixel unit should be reduced. To achieve this, wirings included in the pixel circuit need to be arranged at a higher density.

Additional aspects and features of the present disclosure will be set forth, in part, in the description that follows and, in part, will be apparent from the description or may be learned by practice of embodiments of the present disclosure.
According to an embodiment of the present disclosure, a display panel includes a substrate, a conductive layer on the substrate, a plurality of insulating layers on the conductive layer and having a contact opening overlapping the conductive layer; a semiconductor layer within the plurality of insulating layers, the semiconductor layer having a first portion that protrudes beyond an inner wall of the plurality of insulating layers defining the contact opening to be within the contact opening; and a contact metal on the plurality of insulating layers and extending into the contact opening to contact both the semiconductor layer and the conductive layer.

The contact metal may have a side portion on an inner wall of the plurality of insulating layers defining the contact opening, and a lower portion integrally connected to the side portion and in direct contact with a portion of an upper surface of the conductive layer. The semiconductor layer may be in direct contact with the side portion of the contact metal.

The contact metal may have an upper portion that is integrally connected to the side portion and on an upper surface of the plurality of insulating layers, and a thickness of the side portion may be in a range of 10% to 15% of a thickness of the upper portion.

A length of the first portion of the semiconductor layer may be in a range of 10% to 15% of the thickness of the upper portion of the contact metal.

A length of the first portion of the semiconductor layer may be 150% or less of a thickness of the semiconductor layer.

Inner walls of each of the plurality of insulating layers defining the contact opening may be located on a same surface.

A depth of the contact opening may be greater than a width of the contact opening.

A side surface of the first portion of the semiconductor layer may be covered by the contact metal.

The display panel may further include a light-emitting diode on the contact metal and electrically connected to the semiconductor layer.

According to another embodiment of the present disclosure, a method of manufacturing a display panel includes disposing, on a substrate, a conductive layer, a plurality of insulating layers on the conductive layer, and a semiconductor layer within the plurality of insulating layers, forming a contact opening overlapping the conductive layer and the semiconductor layer in the plurality of insulating layers to expose an upper surface of the conductive layer and a portion of the semiconductor layer, and disposing a contact metal on the plurality of insulating layers to extend into the contact opening in the plurality of insulating layers and to be in direct contact with the conductive layer and the semiconductor layer. The forming of the contact opening includes exposing an upper surface, a side surface, and a lower surface of a first portion of the semiconductor layer overlapping the contact opening.

The contact metal may have a side portion on an inner wall of the plurality of insulating layers defining the contact opening and a lower portion integrally connected to the side portion and in direct contact with a portion of the upper surface of the conductive layer. The semiconductor layer may be in direct contact with the side portion of the contact metal.

The contact metal may have an upper portion that is integrally connected to the side portion and is on an upper surface of the plurality of insulating layers, and a thickness of the side portion may be in a range of 10% to 15% of a thickness of the upper portion.

The first portion of the semiconductor layer may protrude from the inner wall of the plurality of insulating layers defining the contact opening, and a length of the first portion measured in a direction from the inner wall of the plurality of insulating layers toward the contact opening may be in a range of 10% to 15% of the thickness of the upper portion of the contact metal.

The length of the first portion, measured in the direction from the inner wall of the plurality of insulating layers toward the contact opening, may be 150% or less of a thickness of the semiconductor layer.

Some of the plurality of insulating layers may include materials having different etch selectivities, and the forming of the contact opening in the plurality of insulating layers may include etching the plurality of insulating layers such that a width of an opening in one of the plurality of insulating layers is different from a width of an opening in another of the plurality of insulating layers.

The forming of the contact opening in the plurality of insulating layers may include additionally processing some of the plurality of insulating layers such that widths of the openings in the plurality of insulating layers are same.

A depth of the contact opening may be greater than a width of the contact opening.

The contact metal may cover a side surface of the first portion of the semiconductor layer.

According to another embodiment of the present disclosure, an electronic device includes a display panel and a processor configured to drive the display panel. The display panel includes a substrate, a conductive layer on the substrate, a plurality of insulating layers on the conductive layer and having a contact opening overlapping the conductive layer; a semiconductor layer within the plurality of insulating layers, the semiconductor layer having a first portion that protrudes beyond an inner wall of the plurality of insulating layers defining the contact opening to be within the contact opening; and a contact metal on the plurality of insulating layers and extending into the contact opening to contact both the semiconductor layer and the conductive layer.

The contact metal may have a side portion on an inner wall of the plurality of insulating layers defining the contact opening and in direct contact with the semiconductor layer, a lower portion integrally connected to the side portion and in direct contact with a portion of an upper surface of the conductive layer, and an upper portion integrally connected to the side portion and on an upper surface of the plurality of insulating layers, and a thickness of the side portion may be in a range of 10% to 15% of a thickness of the upper portion.

### BRIEF DESCRIPTION OF THE DRAWINGS

The above and other aspects and features of embodiments of the present disclosure will be more apparent from the following description taken in conjunction with the accompanying drawings, in which:

FIG. 1 is a block diagram describing an electronic device according to an embodiment.

FIGS. 2, 3, and 4 are schematic diagrams of electronic devices according to various embodiments.

FIG. 5 is a schematic plan view of an electronic device according to an embodiment.

FIG. 6 is an equivalent circuit diagram of a light-emitting diode of a display panel and a circuit connected to the light-emitting diode according to an embodiment.

FIG. 7 is a cross-sectional view of a display panel according to an embodiment.

FIG. 8 is an enlarged cross-sectional view of a display panel according to an embodiment.

FIG. 9 is an enlarged plan view of a display panel according to an embodiment.

FIG. 10A is a schematic cross-sectional view of a step of a manufacturing process of a display panel according to an embodiment.

FIG. 10B is a schematic plan view of a step of a manufacturing process of a display panel according to an embodiment.

FIG. 11A is a schematic cross-sectional view of a step of a manufacturing process of a display panel according to an embodiment.

FIG. 11B is a schematic plan view of a step of a manufacturing process of a display panel according to an embodiment.

FIG. 12A is a schematic cross-sectional view of a step of a manufacturing process of a display panel according to an embodiment.

FIG. 12B is a schematic plan view of a step of a manufacturing process of a display panel according to an embodiment.

FIG. 13A is a schematic cross-sectional view of a step of a manufacturing process of a display panel according to an embodiment.

FIG. 13B is a schematic plan view of a step of a manufacturing process of a display panel according to an embodiment.

### DETAILED DESCRIPTION

Reference will now be made, in detail, to embodiments, examples of which are illustrated in the accompanying drawings. In this regard, the illustrated embodiments may have different forms and should not be construed as being limited to the descriptions set forth herein. Accordingly, embodiments are merely described below, by referring to the figures, to explain aspects and features of the present description.

Because the present disclosure allows for various changes and numerous embodiments, particular embodiments will be illustrated in the drawings and described in detail in the written description. The attached drawings illustrate embodiments to provide a sufficient understanding of aspects and features of the present disclosure. However, the present disclosure is not limited to the embodiments disclosed below and may be implemented in various different forms.

In the following embodiments, when an element such as a layer, a film, a region, and a board is referred to as being “on” another element, the element may be directly on another element or intervening elements. For convenience of explanation, in the drawings, the size of components may be exaggerated or reduced. Sizes and thicknesses of the elements shown in the drawings are for the purpose of descriptive convenience, and thus the present disclosure is not necessarily limited thereto.

As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list.

In the following embodiments, terms such as “first” and “second” are used for the purpose of distinguishing one component from another component without a limiting meaning.

In the following embodiments, terms such as “comprise (include)” or “have” represent that the features or elements described in the specification exist, and do not preclude the possibility that one or more other features or elements may be added.

In this specification, the expression “A and/or B” represents the case of A, B, or A and B. In addition, the expression “at least one of A and B” represents the case of A, B, or A and B.

In the following embodiments, when films, regions, components, and the like are connected, this includes the case in which films, regions, and components are directly connected, or/and the case in which other films, regions, and components are located between the films, regions, and components. For example, when a film, a region, a component, and the like are electrically connected in this specification, this represents the case in which a film, a region, a component, and the like are directly electrically connected, and/or indirect electrical connection in which another film, region, component, and the like are located therebetween.

In the following embodiments, the expression ‘x direction’ may refer to the +x direction and the-x direction, i.e., the ±x direction. In the following embodiments, the expression ‘y direction’ may refer to the +y direction and the −y direction, i.e., the ±y direction. In the following embodiments, the expression ‘z direction’ may refer to the +z direction and the −z direction, i.e., the ±z direction.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

A display device according to embodiments may be applied to various electronic devices. An electronic device according to an embodiment may include a display device and may further include a module or device having additional functions in addition to the display device. A display device according to an embodiment may include a display panel.

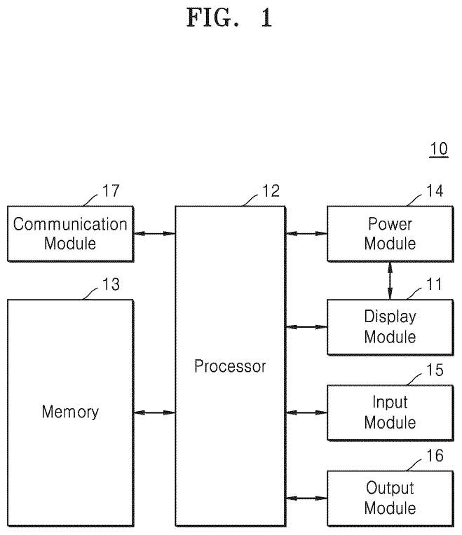

FIG. 1 is a block diagram describing an electronic device 10 according to an embodiment. Referring to FIG. 1, the electronic device 10 may include a display panel 11, a processor 12, memory 13, and a power module 14.

The processor 12 may include at least one of a central processing unit (CPU), an application processor (AP), a graphic processing unit (GPU), a communication processor (CP), an image signal processor (ISP), or a controller. In an embodiment, the processor 12 may be provided as (e.g., may be divided into) two or more according to a functional or structural aspect. For example, the processor 12 may include a main processor in the form of a first drive chip including a CPU and an auxiliary processor in the form of a second drive chip including a controller that receives an image signal from the main processor and processes the image signal to match the interface specifications of the display panel 11.

The memory 13 may include at least one of non-volatile memory or volatile memory. Data information necessary for an operation of the processor 12 or display panel 11 may be stored in the memory 13. When the processor 12 executes an application stored in the memory 13, an image data signal and/or an input control signal may be transferred to the display panel 11, and the display panel 11 may process the received signal and may output image information through (or via) a display screen.

The power module 14 may include a power supply module, such as a power adapter or a battery device, and a power conversion module that converts power supplied by the power supply module to generate power for an operation of the electronic device 10. Power conversion by the power conversion module may include, but is not limited to, direct current (DC)-DC conversion, alternating current (AC)-DC conversion, and DC-AC conversion.

The electronic device 10 may further include an input module 15, a non-image output module 16, and/or a communication module 17.

The input module 15 may provide input information to the processor 12 and/or the display panel 11. The input module 15 may include various sensor modules as well as a physical button, a keyboard, and a microphone. Examples of the sensor modules may include a touch sensor, a pressure sensor, a distance sensor, a position sensor, a digitizer, a motion recognition sensor, a camera sensor, a photodetector, a photoelectric conversion sensor, and a temperature sensor as well as biosensor, such as a blood pressure sensor, a blood sugar sensor, an electrocardiogram sensor, and a heart rate sensor.

The non-image output module 16 may receive information other than the image received from the processor 12 and may provide the information to a user. Examples of the non-image output module 16 may include a sound module, a haptic module, and a light-emitting module and may include other functional modules dedicated to electronic devices (e.g., a cooling module of a refrigerator).

The communication module 17 may be a module for transmitting and receiving information between the electronic device 10 and an external device and may include a receiver and a transmitter. The communication module 17 may include various wireless communication modules such as a mobile communication module, a Wi-Fi module, a Bluetooth module, or various wired communication modules.

At least one of the components described above of the electronic device 10 may be included in the display device. Some of separate modules included in a functionally single module may be provided in the display device and some other ones may be provided separately from the display device. For example, the display device may include the display panel 11, and the processor 12, the memory 13, and the power module 14 may be provided in the form of other devices within the electronic device 10 other than the display device. As another example, the power module 14 may be provided within the display device and may supply power to the processor 12 and the memory 13 provided within the electronic device 10 other than the display device, but the present disclosure is not limited to the above examples.

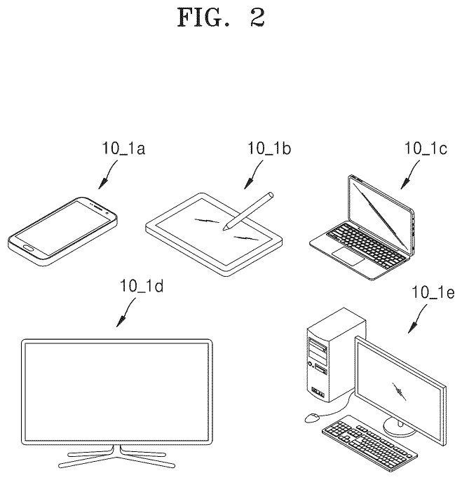

FIGS. 2 to 4 are schematic diagrams of electronic devices according to various embodiments. FIGS. 2 to 4 illustrate examples of various electronic devices to which display panels according to embodiments are applied.

FIG. 2 illustrates examples of an electronic device, including a smartphone 10_1a, a tablet personal computer (PC) 10_1b, a laptop 10_1c, a TV 10_1d, and a desk monitor 10_1e.

The smartphone 10_1a may include an input module, such as a touch sensor and a communication module, as well as a display panel. The smartphone 10_1a may process information received through the communication module or another input module and may display the information through a display panel of the display device.

The tablet PC 10_1b, the laptop 10_1c, the TV 10_1d, and the desk monitor 10_1e may also include a display panel and an input module similar to the smartphone 10_1a, and, in some embodiments, may further include a communication module.

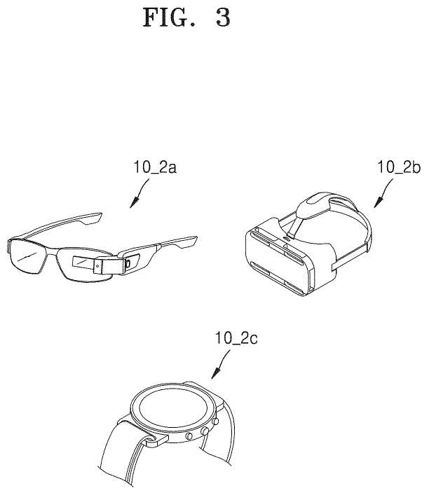

FIG. 3 illustrates examples in which an electronic device including a display panel is applied to a wearable electronic device. The wearable electronic device may include smart glasses 10_2a, a head mounted display 10_2b, and a smart watch 10_2c.

The smart glasses 10_2a and the head mounted display 10_2b may include a display panel that emits a display image and a reflector that reflects the emitted display image and provides the display image to the eyes of a user, thereby providing a virtual reality or augmented reality interface (or screen) to the user.

The smart watch 10_2c may include a biosensor as an input device and may provide biometric information recognized by the biosensor to the user through the display panel.

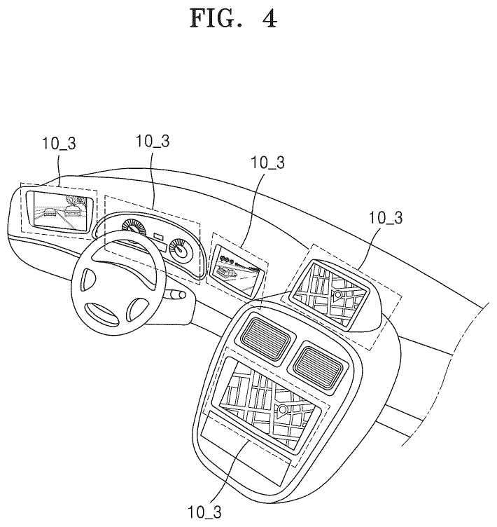

FIG. 4 illustrates an example in which an electronic device including a display panel is applied to a vehicle. For example, an electronic device 10_3 may be applied to a dashboard, center fascia, or the like of a car, or to a center information display (CID) located on the dashboard of the car or a room mirror display replacing a side mirror.

The electronic device to which the display panel, according to embodiments, is applied may include not only devices that primarily features a screen, such as a billboard, an electronic board, and a game console, but also various home appliances that display information through the display panel, such as a refrigerator, a washing machine, a dryer, an air conditioner, and a robot vacuum cleaner. When the display panel has a function of transmitting light, the display panel may be applied to an electronic device, such as a smart window or a transparent display device that displays a background together with a displayed image. The type of an electronic device according to an embodiment is not limited to the above examples, and application of various other electronic devices may also be possible.

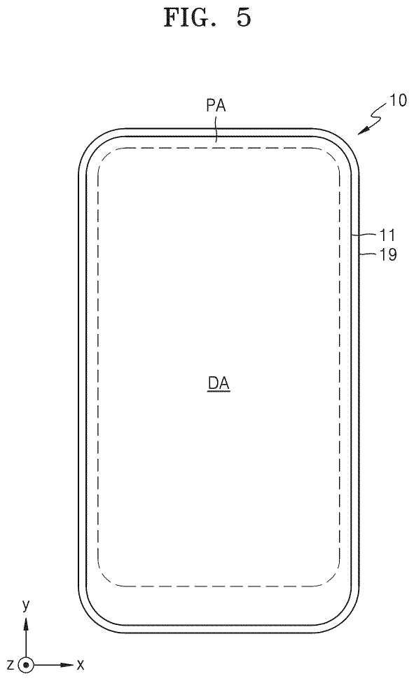

FIG. 5 is a schematic plan view of the electronic device 10 according to an embodiment.

FIG. 5 illustrates an embodiment in which the electronic device 10 is a smartphone, but this is for convenience of description and the present disclosure is not limited thereto. The electronic device 10 may include the display panel 11 and a housing 19. In an embodiment, the display panel 11 may be accommodated within the housing 19. The housing 19 is not necessarily implemented in the form shown in FIG. 5, and the housing 19 referred to in this specification is without limitation in type or form as long as a space in which the display panel 11 is to be accommodated is provided thereby. For example, the housing 19 may not need to completely surround (or complete extend around) the display panel 11 and may partially cover the display panel 11.

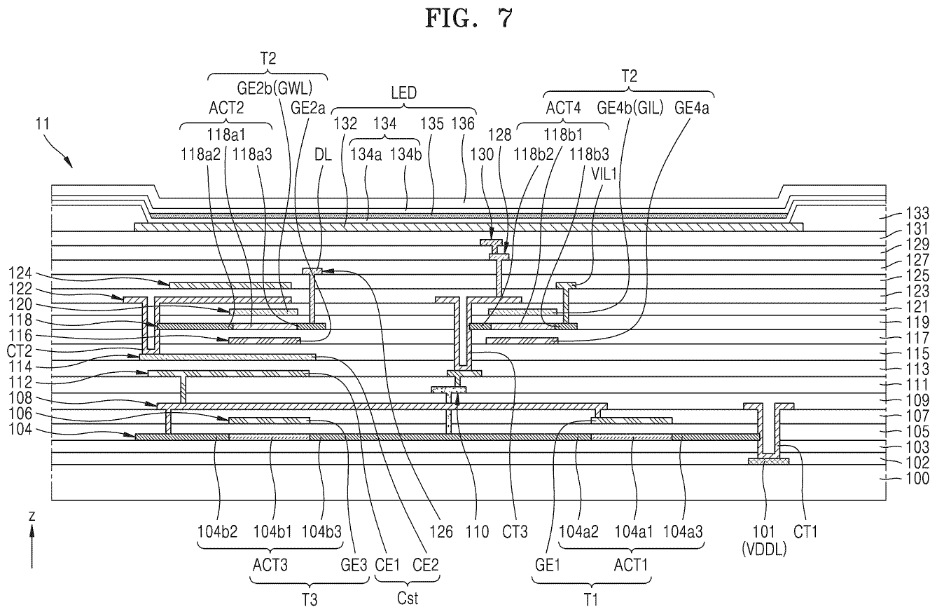

Referring to FIG. 5, the display panel 11 may have a display area DA and a peripheral area PA outside the display area DA. For example, the display area DA and the peripheral area PA outside the display area DA may be defined on the display panel 11. The display panel 11 may include a substrate 100 (see, e.g., FIG. 7), and the display area DA and the peripheral area PA may be defined on the substrate 100.

A pixel may be located in the display area DA. The pixel may include at least one light-emitting diode and a pixel circuit connected to the light-emitting diode to drive the light-emitting diode. The light-emitting diode driven by the pixel circuit may emit light of a specific color (e.g., wavelength). The display panel 11 may provide images and/or videos through light emitted from a plurality of light-emitting diodes provided in a plurality of pixels. In an embodiment, the pixel may include a plurality of grouped (or adjacent) subpixels. In an embodiment, one subpixel may be provided with one corresponding light-emitting diode and one subpixel circuit. In an embodiment, light-emitting diodes provided in each of the plurality of subpixels grouped into one pixel may emit light of different colors (e.g., wavelengths). The peripheral area PA may be a non-display area, and a signal line and/or a voltage line for driving the light-emitting diode may be arranged in the peripheral area PA.

FIG. 5 illustrates that the display panel 11 and the display area DA are approximately rectangular with rounded corners, but the present disclosure is not necessarily limited thereto. The display panel 11 and/or the display area DA may have various shapes, such as polygonal, circular, oval, or irregular shapes.

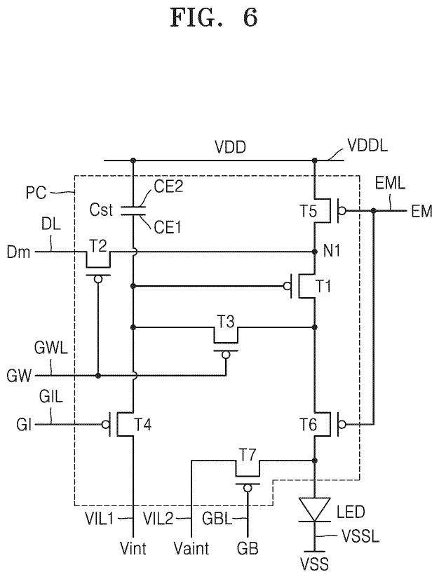

FIG. 6 is an equivalent circuit diagram illustrating a light-emitting diode LED of a display panel and a circuit connected to the light-emitting diode LED according to an embodiment. The display panel 11 described with reference to FIG. 5 may provide an image through pixels arranged two-dimensionally in the display area DA. Each pixel may include the light-emitting diode LED. When the display panel 11 shown in FIG. 5 includes pixels arranged two-dimensionally in the display area DA, the display panel 11 includes light-emitting diodes LEDs arranged two-dimensionally in the display area DA. The light-emitting diode LED is electrically connected to a pixel circuit PC. The pixel circuit PC may be located in the display area DA, similarly to the light-emitting diode LED.

The pixel circuit PC may include a first transistor T1, a second transistor T2, a third transistor T3, a fourth transistor T4, a fifth transistor T5, a sixth transistor T6, a seventh transistor T7, and a storage capacitor Cst. The first transistor T1 is a driving transistor, and the second transistor T2, the third transistor T3, the fourth transistor T4, the fifth transistor T5, the sixth transistor T6, and the seventh transistor T7 are switching transistors.

The first to seventh transistors T1, T2, T3, T4, T5, T6, and T7 may be provided as a p-channel MOSFET (PMOS) or an n-channel MOSFET (NMOS). In an embodiment, FIG. 6 illustrates that the first to seventh transistors T1, T2, T3, T4, T5, T6, and T7 are each a PMOS. The first to seventh transistors T1, T2, T3, T4, T5, T6, and T7 may each be a transistor having a low-temperature polycrystalline silicon (LTPS) semiconductor layer.

FIG. 6 illustrates that the first to seventh transistors T1, T2, T3, T4, T5, T6, and T7 are each a PMOS, but the present disclosure is not limited thereto. In another embodiment, each of the first to seventh transistors T1, T2, T3, T4, T5, T6, and T7 may be an NMOS. In an embodiment, at least one of the first to seventh transistors T1, T2, T3, T4, T5, T6, and T7 may be provided as a PMOS or an NMOS. For example, from among the first to seventh transistors T1, T2, T3, T4, T5, T6, and T7, the third transistor T3 and the fourth transistor T4 may each be an NMOS, and the other transistors may each be a PMOS. For example, from among the first to seventh transistors T1, T2, T3, T4, T5, T6, and T7, the fifth transistor T5 may a p-channel MOSFET (PMOS), and the other transistors may each be an n-channel MOSFET (NMOS).

FIG. 6 illustrates an embodiment in which the first to seventh transistors T1, T2, T3, T4, T5, T6, and T7 are transistors having an LTPS semiconductor layer, but the present disclosure is not limited thereto. In another embodiment, the first to seventh transistors T1, T2, T3, T4, T5, T6, and T7 may each be a transistor having an oxide semiconductor layer. In an embodiment, at least one of the first to seventh transistors T1, T2, T3, T4, T5, T6, and T7 may each be a transistor having an LTPS semiconductor layer, and the other transistors may each be a transistor having an oxide semiconductor layer. In an embodiment, the third transistor T3 and the fourth transistor T4 may include an oxide semiconductor layer having a low leakage current, and the first, second, fifth, sixth, and seventh transistors T1, T2, T5, T6, and T7 may include a semiconductor layer including polycrystalline silicon. In an embodiment, the fifth transistor T5 may include a semiconductor layer including polycrystalline silicon, and the first, second, third, fourth, sixth, and seventh transistors T1, T2, T3, T4, T6, and T7 may include an oxide semiconductor layer.

The pixel circuit PC is electrically connected to signal lines and voltage lines. The signal lines may include a gate line, such as a scan signal line GWL, a bypass control line GBL, an initialization control line GIL, an emission control line EML, and a data line DL. The voltage lines may include first and second initialization voltage lines VIL1 and VIL2 and a first voltage line VDDL.

The first voltage line VDDL may transfer a first power supply voltage VDD to the first transistor T1. A first initialization voltage line VIL1 may transfer a first initialization voltage Vint that initializes the first transistor T1 to the pixel circuit PC. A second initialization voltage line VIL2 may transfer a second initialization voltage Vaint that initializes a first electrode of the light-emitting diode LED to the pixel circuit PC.

The first transistor T1 may be electrically connected to the first voltage line VDDL via the fifth transistor T5 and may be electrically connected to the light-emitting diode LED via the sixth transistor T6. The first transistor T1 acts as a driving transistor and receives a data signal Dm according to a switching operation of the second transistor T2 and supplies driving current to the light-emitting diode LED.

The second transistor T2 is a data writing transistor and is electrically connected to the scan signal line GWL and the data line DL. The second transistor T2 is electrically connected to the first voltage line VDDL via the fifth transistor T5. The second transistor T2 is turned on according to a scan signal GW received through the scan signal line GWL to perform a switching operation of transferring the data signal Dm transferred through the data line DL to a first node N1.

The third transistor T3 is electrically connected to the scan signal line GWL and electrically connected to the light-emitting diode LED via the sixth transistor T6. The third transistor T3 may be turned on according to the scan signal GW received through the scan signal line GWL to diode-connect the first transistor T1.

The fourth transistor T4 is a first initialization transistor and is electrically connected to the initialization control line GIL and the first initialization voltage line VIL1. The fourth transistor T4 is turned on according to an initialization control signal GI received through the initialization control line GIL and may transfer the first initialization voltage Vint from the first initialization voltage line VIL1 to a gate electrode of the first transistor T1 to initialize a voltage of a gate electrode of the first transistor T1. The initialization control signal GI may correspond to a scan signal of another pixel circuit located in a previous row of a corresponding pixel circuit PC.

The fifth transistor T5 may be a motion control transistor, and the sixth transistor T6 may be a light emission control transistor. The fifth transistor T5 and the sixth transistor T6 are electrically connected to the emission control line EML and are turned on concurrently (or simultaneously) according to an emission control signal EM received through the emission control line EML to form a current path such that driving current may flow from the first voltage line VDDL in a direction toward the light-emitting diode LED. A first electrode of the light-emitting diode LED may be electrically connected to the first transistor T1 through the sixth transistor T6, and a second electrode may be electrically connected to a second voltage line VSSL to supply a second power voltage VSS.

The seventh transistor T7 may be a second initialization transistor and may be electrically connected to the bypass control line GBL, the second initialization voltage line VIL2, and the sixth transistor T6. The seventh transistor T7 may be turned on according to a bypass control signal GB received through the bypass control line GBL and may transfer the second initialization voltage Vaint from the second initialization voltage line VIL2 to the first electrode of the light-emitting diode LED to initialize the first electrode of the light-emitting diode LED.

The storage capacitor Cst includes a first capacitor electrode CE1 and a second capacitor electrode CE2. The first capacitor electrode CE1 is electrically connected to the gate electrode of the first transistor T1, and the second capacitor electrode CE2 is electrically connected to the first voltage line VDDL. The storage capacitor Cst may maintain a voltage applied to the gate electrode of the first transistor T1 by storing and maintaining a voltage corresponding to a voltage difference between the first voltage line VDDL and the gate electrode of the first transistor T1.

FIG. 6 illustrates an embodiment in which the first and second initialization voltage lines VIL1 and VIL2 are electrically connected to the fourth transistor T4 and the seventh transistor T7, respectively, but the present disclosure is not limited thereto. In another embodiment, the first and second initialization voltage lines VIL1 and VIL2 are the same initialization voltage line, and a single initialization voltage line may be electrically connected to each of the fourth transistor T4 and the seventh transistor T7.

FIG. 6 illustrates an embodiment in which the pixel circuit PC includes seven transistors and one capacitor, but the present disclosure is not limited thereto. In another embodiment, the pixel circuit PC may include three, four, five, or six transistors, eight or more transistors, or two or more capacitors.

FIG. 7 is a cross-sectional view of a display panel according to an embodiment. FIG. 7 may be a cross-sectional view of the display area DA (see, e.g., FIG. 5) of the display panel 11.

Referring to FIG. 7, the display panel 11 may include the substrate 100, the light-emitting diode LED on the substrate 100, and a circuit layer between the substrate 100 and the light-emitting diode LED. The circuit layer may include the pixel circuit PC (see, e.g., FIG. 6) electrically connected to the light-emitting diode LED. The pixel circuit PC may include transistors and a capacitor as described with reference to FIG. 6, and according to an embodiment, FIG. 7 illustrates the first to fourth transistors T1, T2, T3, and T4 and the storage capacitor Cst from among the transistors described with reference to FIG. 6.

The substrate 100 may include various suitable materials, such as glass, or a plastic material, such as polyethylene terephthalate (PET), polyethylene naphthalate (PEN), or polyimide. When the substrate 100 includes a plastic material, flexibility of the substrate 100 may be improved compared to when the substrate 100 include a glass material. The substrate 100 may have a multilayer structure including at least one substrate layer including the material as described above and at least one barrier layer including an insulator (e.g., an inorganic insulator).

A first conductive layer 101 may be disposed on the substrate 100. The first conductive layer 101 may include the first voltage line VDDL. The first voltage line VDDL may partially overlap a first active layer ACT1 of the first transistor T1. In an embodiment, the first conductive layer 101 may include a shield pattern disposed under a first semiconductor layer 104, for example, the first active layer ACT1 and/or a third active layer ACT3. In an embodiment, the first conductive layer 101 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

A first insulating layer 102 may be disposed on the first conductive layer 101. The first insulating layer 102 may be partially opened (e.g., may have an opening) to cover an edge region (e.g., an edge) of the first voltage line VDDL. For example, the first insulating layer 102 may have an opening that overlaps a center portion of the first voltage line VDDL. In an embodiment, the first insulating layer 102 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the first insulating layer 102 may include silicon nitride (SiNₓ). In an embodiment, the first insulating layer 102 may be a first buffer layer.

A second insulating layer 103 may be disposed on the first insulating layer 102. The second insulating layer 103 may have an opening that overlaps a center portion of the first voltage line VDDL. The opening in the first insulating layer 102 and the opening in the second insulating layer 103 described above may overlap each other. In an embodiment, the second insulating layer 103 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the second insulating layer 103 may include silicon oxide (SiO₂). In an embodiment, the second insulating layer 103 may be a second buffer layer.

The first transistor T1 and the third transistor T3 may be disposed on the second insulating layer 103. The first transistor T1 may include the first active layer ACT1 and a first gate electrode GE1. The first gate electrode GE1 may be disposed on the first active layer ACT1. The third transistor T3 may include the third active layer ACT3 and a third gate electrode GE3. The third gate electrode GE3 may be disposed on the third active layer ACT3.

The first semiconductor layer 104 may be disposed on the second insulating layer 103. The first semiconductor layer 104 may include the first active layer ACT1 and the third active layer ACT3. In an embodiment, the first active layer ACT1 and the third active layer ACT3 may be provided integrally (e.g., may be integrally formed) as illustrated in FIG. 7. In another embodiment, the first active layer ACT1 and the third active layer ACT3 may be separated from (or separate from) each other. In an embodiment, the first semiconductor layer 104 may include a polysilicon semiconductor. For example, the first semiconductor layer 104 may include low-temperature polycrystalline silicon (LTPS).

The first active layer ACT1 may be provided on one side of the first semiconductor layer 104. The first active layer ACT1 may have a first channel region 104a1, a first source region 104a2, and a first drain region 104a3. The first channel region 104a1 may be located between the first source region 104a2 and the first drain region 104a3. The first source region 104a2 and the first drain region 104a3 may be regions doped with impurities (e.g., dopants). In an embodiment, the positions of the first source region 104a2 and the first drain region 104a3 may be changed or reversed.

The third active layer ACT3 may be provided on one side of the first semiconductor layer 104. The third active layer ACT3 may have a third channel region 104b1, a third source region 104b2, and a third drain region 104b3. The third channel region 104b1 may be located between the third source region 104b2 and the third drain region 104b3. The third source region 104b2 and the third drain region 104b3 may be regions doped with impurities (e.g., dopants). In an embodiment, the positions of the third source region 104b2 and the third drain region 104b3 may be changed or reversed.

A third insulating layer 105 may be disposed on the first semiconductor layer 104. The third insulating layer 105 may be located (or arranged) between the first semiconductor layer 104 and a second conductive layer 106 to insulate the first semiconductor layer 104 and the second conductive layer 106 from each other. In an embodiment, the third insulating layer 105 may insulate the first active layer ACT1 from the first gate electrode GE1. In an embodiment, the third insulating layer 105 may insulate the third active layer ACT3 from the third gate electrode GE3. In an embodiment, the third insulating layer 105 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the third insulating layer 105 may include silicon oxide (SiO₂). In an embodiment, the third insulating layer 105 may be a first gate insulating layer.

The third insulating layer 105 may have an opening that overlaps a center portion of the first voltage line VDDL. The opening in the first insulating layer 102, the opening in the second insulating layer 103, and the opening in the third insulating layer 105 may overlap each other. The third insulating layer 105 may not cover (e.g., may expose) a portion of an upper surface of the first active layer ACT1, for example, a portion of an upper surface of the first drain region 104a3. A portion of the first active layer ACT1, for example, a portion of the first drain region 104a3, may protrude into the opening in the third insulating layer 105. A lower surface of a portion of the first active layer ACT1 protruding into the opening in the third insulating layer 105 may not be covered by (e.g., may be exposed by or through) the second insulating layer 103.

The second conductive layer 106 may be disposed on the third insulating layer 105. The second conductive layer 106 may include the first gate electrode GE1 and the third gate electrode GE3. The first gate electrode GE1 may overlap first channel region 104a1 of the first active layer ACT1. The third gate electrode GE3 may overlap the third channel region 104b1 of the third active layer ACT3. In an embodiment, the second conductive layer 106 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

A fourth insulating layer 107 may be disposed on the second conductive layer 106. The fourth insulating layer 107 may cover the second conductive layer 106, for example, the first gate electrode GE1 and the third gate electrode GE3. The fourth insulating layer 107 may have an opening that overlaps the center portion of the first voltage line VDDL. The opening in the first insulating layer 102, the opening in the second insulating layer 103, the opening in the third insulating layer 105, and the opening in the fourth insulating layer 107 may overlap each other. In an embodiment, the fourth insulating layer 107 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the fourth insulating layer 107 may include silicon nitride (SiNₓ). In an embodiment, the fourth insulating layer 107 may be a second gate insulating layer.

A third conductive layer 108 may be disposed on the fourth insulating layer 107. A portion of the third conductive layer 108 may be connected to the third active layer ACT3 (e.g., the third source region 104b2) through the openings defined in the third insulating layer 105 and the fourth insulating layer 107 and connected to the first gate electrode GE1 through the opening defined in the fourth insulating layer 107 to electrically connect the third active layer ACT3 to the first gate electrode GE1. The third conductive layer 108 may include a first contact metal CT1. A portion of the first contact metal CT1 may be disposed on an upper surface of the fourth insulating layer 107. A portion of the first contact metal CT1 may extend into the openings defined in the first to fourth insulating layers 102, 103, 105, and 107. The first contact metal CT1 may be in direct contact with the first active layer ACT1 (e.g., the first drain region 104a3) and may be in direct contact with the first voltage line VDDL (e.g., the upper surface of the first voltage line VDDL). The first active layer ACT1 and the first voltage line VDDL may be electrically connected through the first contact metal CT1. The first contact metal CT1 may cover a portion of the first active layer ACT1 that protrudes into the opening defined in the third insulating layer 105. In an embodiment, the third conductive layer 108 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

A fifth insulating layer 109 may be disposed on the third conductive layer 108. The fifth insulating layer 109 may cover a fourth conductive layer 110. For example, the fifth insulating layer 109 may cover the first contact metal CT1. In an embodiment, the fifth insulating layer 109 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the fifth insulating layer 109 may be a third gate insulating layer.

The fourth conductive layer 110 may be disposed on the fifth insulating layer 109. A portion of a fifth conductive layer 112 may be connected to the first semiconductor layer 104, for example, the third active layer ACT3, for example, the third drain region 104b3, through the openings defined in the third to fifth insulating layers 105, 107, and 109. In an embodiment, the fourth conductive layer 110 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

A sixth insulating layer 111 may be disposed on the fourth conductive layer 110. The sixth insulating layer 111 may cover the fourth conductive layer 110. In an embodiment, the sixth insulating layer 111 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the sixth insulating layer 111 may be a fourth gate insulating layer.

The storage capacitor Cst may be disposed on the sixth insulating layer 111. The storage capacitor Cst may include the first capacitor electrode CE1 and the second capacitor electrode CE2. The first capacitor electrode CE1 and the second capacitor electrode CE2 may overlap each other and be insulated from each other by a seventh insulating layer 113.

The fifth conductive layer 112 may be disposed on the sixth insulating layer 111. The fifth conductive layer 112 may include the first capacitor electrode CE1. A portion of the fifth conductive layer 112, for example, the first capacitor electrode CE1, may be connected to the third conductive layer 108 through the openings defined in the fifth insulating layer 109 and the sixth insulating layer 111. The first capacitor electrode CE1 may be electrically connected to the first gate electrode GE1 and the third active layer ACT3 (e.g., the third source region 104b2) through the third conductive layer 108. A portion of the fifth conductive layer 112 may be connected to the fourth conductive layer 110 through the opening defined in the sixth insulating layer 111. In an embodiment, the fifth conductive layer 112 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

The seventh insulating layer 113 may be disposed on the fifth conductive layer 112. The seventh insulating layer 113 may cover the fifth conductive layer 112, for example, the first capacitor electrode CE1. The seventh insulating layer 113 may have an opening that overlaps a portion of the fifth conductive layer 112. In an embodiment, the seventh insulating layer 113 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the seventh insulating layer 113 may be a fifth gate insulating layer.

A sixth conductive layer 114 may be disposed on the seventh insulating layer 113. The sixth conductive layer 114 may include the second capacitor electrode CE2. In an embodiment, the sixth conductive layer 114 may include a conductive material such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

An eighth insulating layer 115 may be disposed on the sixth conductive layer 114. The eighth insulating layer 115 may cover the sixth conductive layer 114, for example, the second capacitor electrode CE2. The eighth insulating layer 115 may have an opening that overlaps the second capacitor electrode CE2, and the eighth insulating layer 115 may have an opening that overlaps a portion of the fifth conductive layer 112. In an embodiment, the eighth insulating layer 115 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the eighth insulating layer 115 may be a sixth gate insulating layer.

The second transistor T2 and the fourth transistor T4 may be disposed on the eighth insulating layer 115. The second transistor T2 may include a second active layer ACT2, a 2^{nd}-1 gate electrode GE2a, and a 2^{nd}-2 gate electrode GE2b. The 2^{nd}-1 gate electrode GE2a may be disposed below the second active layer ACT2, and the 2^{nd}-2 gate electrode GE2b may be disposed on the second active layer ACT2. The fourth transistor T4 may include a fourth active layer ACT4, a 4^{th}-1 gate electrode GE4a, and a 4^{th}-2 gate electrode GE4b. The 4^{th}-1 gate electrode GE4a may be disposed below the fourth active layer ACT4, and the 4^{th}-2 gate electrode GE4b may be disposed on the fourth active layer ACT4.

A seventh conductive layer 116 may be disposed on the eighth insulating layer 115. The seventh conductive layer 116 may include the 2^{nd}-1 gate electrode GE2a and the 4^{th}-1 gate electrode GE4a. The 2^{nd}-1 gate electrode GE2a may overlap a second channel region 118a1 of the second active layer ACT2. The 4^{th}-1 gate electrode GE4a may overlap a fourth channel region 118b1 of the fourth active layer ACT4. In an embodiment, the seventh conductive layer 116 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

A ninth insulating layer 117 may be disposed on the seventh conductive layer 116. The ninth insulating layer 117 may cover the seventh conductive layer 116, for example, the 2^{nd}-1 gate electrode GE2a and the 4^{th}-1 gate electrode GE4a. The ninth insulating layer 117 may be located between the seventh conductive layer 116 and a second semiconductor layer 118 to insulate the seventh conductive layer 116 from the second semiconductor layer 118. In an embodiment, the ninth insulating layer 117 may insulate the 2^{nd}-1 gate electrode GE2a from the second active layer ACT2. In an embodiment, the ninth insulating layer 117 may insulate the 4^{th}-1 gate electrode GE4a from the fourth active layer ACT4. The ninth insulating layer 117 may have an opening that overlaps the second capacitor electrode CE2 and an opening that overlaps a portion of the fifth conductive layer 112. In an embodiment, the ninth insulating layer 117 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the ninth insulating layer 117 may be a seventh gate insulating layer.

The second semiconductor layer 118 may be disposed on the ninth insulating layer 117. The second semiconductor layer 118 may include the second active layer ACT2 and the fourth active layer ACT4. In an embodiment, the second active layer ACT2 and the fourth active layer ACT4 may be provided separately from each other as illustrated in FIG. 7. In an embodiment, the second active layer ACT2 and the fourth active layer ACT4 may be provided integrally (e.g., may be integrally formed). In an embodiment, the second semiconductor layer 118 may include an oxide semiconductor. For example, the second semiconductor layer 118 may include an indium gallium zinc oxide (IGZO) semiconductor.

The second active layer ACT2 may be provided on one side of the second semiconductor layer 118. The second active layer ACT2 may have the second channel region 118a1, a second source region 118a2, and a second drain region 118a3. The second channel region 118a1 may be located between the second source region 118a2 and the second drain region 118a3. The second source region 118a2 and the second drain region 118a3 may be regions doped with impurities (e.g., dopants). In an embodiment, the positions of the second source region 118a2 and the second drain region 118a3 may be changed or reversed.

The fourth active layer ACT4 may be provided on one side of the second semiconductor layer 118. The fourth active layer ACT4 may have the fourth channel region 118b1, a fourth source region 118b2, and a fourth drain region 118b3. The fourth channel region 118b1 may be located between the fourth source region 118b2 and the fourth drain region 118b3. The fourth source region 118b2 and the fourth drain region 118b3 may be regions doped with impurities (e.g., dopants). In an embodiment, the positions of the fourth source region 118b2 and the fourth drain region 118b3 may be changed or reversed.

A tenth insulating layer 119 may be disposed on the second semiconductor layer 118. The tenth insulating layer 119 may be located between the second semiconductor layer 118 and an eighth conductive layer 120 to insulate the second semiconductor layer 118 from the eighth conductive layer 120. In an embodiment, the tenth insulating layer 119 may insulate the second active layer ACT2 from the 2^{nd}-2 gate electrode GE2b. In an embodiment, the tenth insulating layer 119 may insulate the fourth active layer ACT4 from the 4^{th}-2 gate electrode GE4b. In an embodiment, the tenth insulating layer 119 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the tenth insulating layer 119 may be an eighth gate insulating layer.

The tenth insulating layer 119 may have an opening that overlaps the second active layer ACT2, for example, the second drain region 118a3 and an opening that overlaps the fourth active layer ACT4, for example, the fourth drain region 118b3.

The tenth insulating layer 119 may have an opening that overlaps the second capacitor electrode CE2. The tenth insulating layer 119 may not cover (e.g., may expose) a portion of the upper surface of the second active layer ACT2, for example, a portion of the upper surface of the second source region 118a2. A portion of the second active layer ACT2, for example, a portion of the second source region 118a2, may protrude (or extend) into the opening in the tenth insulating layer 119. A lower surface of a portion of the second active layer ACT2 protruding into the opening in the tenth insulating layer 119 may not be covered by (e.g., may be exposed by or through) the ninth insulating layer 117.

The tenth insulating layer 119 may have an opening that overlaps a portion of the fifth conductive layer 112. The tenth insulating layer 119 may not cover (e.g., may expose) a portion of the upper surface of the fourth active layer ACT4, for example, a portion of the upper surface of the fourth source region 118b2. A portion of the fourth active layer ACT4, for example, a portion of the fourth source region 118b2, may protrude (or may extend) into the opening in the tenth insulating layer 119. A lower surface of a portion of the fourth active layer ACT4 protruding into the opening in the tenth insulating layer 119 may not be covered by (e.g., may be exposed by or through) the ninth insulating layer 117.

The eighth conductive layer 120 may be located on the tenth insulating layer 119. The eighth conductive layer 120 may include the 2^{nd}-2 gate electrode GE2b and the 4^{th}-2 gate electrode GE4b. The 2^{nd}-2 gate electrode GE2b may overlap the second channel region 118a1 of the second active layer ACT2. The 4^{th}-2 gate electrode GE4b may overlap the fourth channel region 118b1 of the fourth active layer ACT4. In an embodiment, the eighth conductive layer 120 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

An eleventh insulating layer 121 may be disposed on the eighth conductive layer 120. The eleventh insulating layer 121 may cover the eighth conductive layer 120, for example, the 2^{nd}-2 gate electrode GE2b and the 4^{th}-2 gate electrode GE4b. The eleventh insulating layer 121 may have an opening that overlaps the second active layer ACT2, for example, the second drain region 118a3, an opening that overlaps the fourth active layer ACT4, for example, the fourth drain region 118b3, an opening that overlaps the second capacitor electrode CE2, and an opening that overlaps a portion of the fifth conductive layer 112. In an embodiment, the eleventh insulating layer 121 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the eleventh insulating layer 121 may be a ninth gate insulating layer.

A ninth conductive layer 122 may be disposed on the eleventh insulating layer 121. The ninth conductive layer 122 may include a second contact metal CT2 and a third contact metal CT3. In an embodiment, the ninth conductive layer 122 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

A portion of the second contact metal CT2 may be disposed on the eleventh insulating layer 121. A portion of the second contact metal CT2 may extend into the openings defined in the eighth to eleventh insulating layers 115, 117, 119, and 121. The second contact metal CT2 may be in direct contact with the second active layer ACT2 (e.g., the second source region 118a2) and may be in direct contact with the second capacitor electrode CE2 (e.g., the upper surface of the second capacitor electrode CE2). The second active layer ACT2 and the second capacitor electrode CE2 may be electrically connected through (or via) the second contact metal CT2. The second contact metal CT2 that protrudes into the opening defined in the tenth insulating layer 119 may cover a portion of the second active layer ACT2.

A portion of the third contact metal CT3 may be disposed on the eleventh insulating layer 121. A portion of the third contact metal CT3 may extend into the opening defined in the seventh to eleventh insulating layers 113, 115, 117, 119, and 121. The third contact metal CT3 may be in direct contact with the fourth active layer ACT4 (e.g., the fourth source region 118b2) and may be in direct contact with a portion (e.g., upper surface) of the fifth conductive layer 112. The fourth active layer ACT4 and the first semiconductor layer 104 (e.g., the third active layer ACT3) may be electrically connected through the third contact metal CT3, the fifth conductive layer 112, and the fourth conductive layer 110. The third contact metal CT3 that protrudes into the opening defined in the tenth insulating layer 119 may cover a portion of the fourth active layer ACT4.

A twelfth insulating layer 123 may be disposed on the ninth conductive layer 122. The twelfth insulating layer 123 may cover the ninth conductive layer 122, for example, the second contact metal CT2 and the third contact metal CT3. The twelfth insulating layer 123 may have an opening that overlaps the second active layer ACT2, for example, the second drain region 118a3, an opening that overlaps the fourth active layer ACT4, for example, the fourth drain region 118b3, and an opening that overlaps the third contact metal CT3. In an embodiment, the twelfth insulating layer 123 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the twelfth insulating layer 123 may be a first interlayer insulating layer.

A tenth conductive layer 124 may be disposed on the twelfth insulating layer 123. A portion of the tenth conductive layer 124 may overlap the second contact metal CT2. A portion of the tenth conductive layer 124 that overlaps the second contact metal CT2 and the second contact metal CT2 may be electrodes of an additional capacitor. The tenth conductive layer 124 may include the first initialization voltage line VIL1. In an embodiment, the first initialization voltage line VIL1 may be connected to the fourth active layer ACT4, for example, the fourth drain region 118b3, through the openings defined in the tenth to twelfth insulating layers 119, 121, and 123. In an embodiment, a portion of the tenth conductive layer 124 that overlaps the first initialization voltage line VIL1 and the second contact metal CT2 may be electrically connected to each other. In an embodiment, the tenth conductive layer 124 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

A thirteenth insulating layer 125 may be disposed on the tenth conductive layer 124. The thirteenth insulating layer 125 may cover the tenth conductive layer 124. The thirteenth insulating layer 125 may have an opening that overlaps the second active layer ACT2, for example, the second drain region 118a3 and an opening that overlaps the third contact metal CT3. In an embodiment, the thirteenth insulating layer 125 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the thirteenth insulating layer 125 may be a second interlayer insulating layer.

An eleventh conductive layer 126 may be disposed on the thirteenth insulating layer 125. The eleventh conductive layer 126 may include the data line DL. The data line DL may be connected to the second active layer ACT2, for example, the second drain region 118a3, through the openings defined in the tenth to thirteenth insulating layers 119, 121, 123, and 125. In an embodiment, the eleventh conductive layer 126 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

A fourteenth insulating layer 127 may be disposed on the eleventh conductive layer 126. The fourteenth insulating layer 127 may cover the eleventh conductive layer 126. The fourteenth insulating layer 127 may have an opening that overlaps the third contact metal CT3. In an embodiment, the fourteenth insulating layer 127 may include an inorganic insulating material, such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), and/or zinc oxide (ZnO₂), and may have a single-layer or multilayer structure of the materials described above. In an embodiment, the fourteenth insulating layer 127 may be a third interlayer insulating layer.

A twelfth conductive layer 128 may be disposed on the fourteenth insulating layer 127. The twelfth conductive layer 128 may be connected to the third contact metal CT3 through the openings defined in the twelfth to fourteenth insulating layers 123, 125, and 127. In an embodiment, the twelfth conductive layer 128 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

FIG. 7 illustrates an embodiment in which the first to fourteenth insulating layers 102, 103, 105, 107, 109, 111, 113, 115, 117, 119, 121, 123, 125, and 127 are planarization layers having planarized (e.g., flat) upper surfaces, but in another embodiment, at least one layer from among the first to fourteenth insulating layers 102, 103, 105, 107, 109, 111, 113, 115, 117, 119, 121, 123, 125, and 127 may have unevenness or curvature depending on the shape of a layer disposed therebelow.

A fifteenth insulating layer 129 may cover the twelfth conductive layer 128. In an embodiment, the fifteenth insulating layer 129 may be a planarization layer. In an embodiment, the fifteenth insulating layer 129 may include an organic insulating material, for example, a general-purpose polymer such as benzocyclobutene (BCB), polyimide, hexamethyldisiloxane (HMDSO), polymethylmethacrylate, or polystyrene, a polymer derivative having a phenol group, an acrylic polymer, an imide polymer, an aryl ether polymer, an amide polymer, a fluorine polymer, a p-xylene polymer, and/or a vinyl alcohol polymer, and may have a single-layer or multilayer structure of the materials described above. In an embodiment, the fifteenth insulating layer 129 may be a first via layer.

A thirteenth conductive layer 130 may be disposed on the fifteenth insulating layer 129. The thirteenth conductive layer 130 may be connected to the twelfth conductive layer 128 through the opening defined in the fifteenth insulating layer 129. In an embodiment, the thirteenth conductive layer 130 may include a conductive material, such as aluminum (Al), platinum (Pt), palladium (Pd), silver (Ag), magnesium (Mg), gold (Au), nickel (Ni), neodymium (Nd), iridium (Ir), chromium (Cr), molybdenum (Mo), titanium (Ti), tungsten (W), and/or copper (Cu), and may have a single-layer or multilayer structure of the materials described above.

A sixteenth insulating layer 131 may cover the thirteenth conductive layer 130. In an embodiment, the sixteenth insulating layer 131 may be a planarization layer. In an embodiment, the sixteenth insulating layer 131 may include an organic insulating material, for example, a general-purpose polymer such as benzocyclobutene, polyimide, hexamethyldisiloxane, polymethylmethacrylate, or polystyrene, a polymer derivative having a phenol group, an acrylic polymer, an imide polymer, an aryl ether polymer, an amide polymer, a fluorine polymer, a p-xylene polymer, and/or a vinyl alcohol polymer, and may have a single-layer or multilayer structure of the materials described above. In an embodiment, the sixteenth insulating layer 131 may be a second via layer.

The light-emitting diode LED may be disposed on the sixteenth insulating layer 131. The light-emitting diode LED may include a first electrode 132, a functional layer 134, an emission layer 135, and a second electrode 136. The first electrode 132 may be disposed on the sixteenth insulating layer 131. The first electrode 132 may be connected to the thirteenth conductive layer 130 through the opening defined in the sixteenth insulating layer 131.

The second electrode 136 may be disposed on the first electrode 132, and the functional layer 134 and the emission layer 135 may be disposed between the first electrode 132 and the second electrode 136. The emission layer 135 may emit light by (or in response to) a current flowing through the emission layer 135 (and/or the functional layer 134) due to a potential difference between the first electrode 132 and the second electrode 136. Light emitted by the light-emitting diode LED corresponds to light emitted by the emission layer 135. In an embodiment, the first electrode 132 may be a pixel electrode or an anode, and the second electrode 136 may be a counter electrode or a cathode. In another embodiment, the second electrode 136 may be a pixel electrode or an anode, and the first electrode 132 may be a counter electrode or a cathode.

The first electrode 132 may be disposed on an eighth insulating layer IL8. The first electrode 132 may include a conductive oxide, such as indium tin oxide (ITO), indium zinc oxide (IZO), zinc oxide (ZnO), indium oxide (In₂O₃), indium gallium oxide (IGO), and/or aluminum zinc oxide (AZO). When the first electrode 132 is a reflective electrode, the first electrode 132 may include a reflective film including at least one selected from among silver (Ag), magnesium (Mg), aluminum (Al), platinum (Pt), palladium (Pd), gold (Au), nickel (Ni), neodymium (Nd), iridium (Ir), chromium (Cr), and a compound thereof. In an embodiment, the first electrode 132 may include indium tin oxide (ITO) and silver (Ag). In an embodiment, the first electrode 132 may include a multilayer structure disposed in the order of indium tin oxide (ITO)-silver (Ag)-indium tin oxide (ITO).

A pixel definition layer 133 may be disposed on the first electrode 132. The pixel definition layer 133 may cover an edge region (or edge) of the first electrode 132. In other words, the pixel definition layer 133 may have an opening that overlaps the center portion of the first electrode 132. An emission area of the light-emitting diode LED may be defined by the opening in the pixel definition layer 133.

The functional layer 134 may be disposed on the first electrode 132. The functional layer 134 may include a first functional layer 134a and a second functional layer 134b. The second functional layer 134b may be disposed on the first functional layer 134a. The emission layer 135 may be located between the first functional layer 134a and the second functional layer 134b. In an embodiment, the first functional layer 134a may be disposed on the pixel definition layer 133, the emission layer 135 may be located in (e.g., within) the opening in the pixel definition layer 133 on the first functional layer 134a, and the second functional layer 134b may be disposed on the first functional layer 134a to cover the emission layer 135. For example, the emission layer 135 may be located in (e.g., within) the opening in the pixel definition layer 133 and may be located between the first functional layer 134a and the second functional layer 134b.

The emission layer 135 may include an organic emission layer containing a low-molecular or high-molecular substance. The first functional layer 134a may include an electron transport layer (ETL) and/or an electron injection layer (EIL). The second functional layer 134b may include a hole transport layer (HTL) and/or a hole injection layer (HIL). In various embodiments, the first functional layer 134a or the second functional layer 134b may be omitted. In an embodiment, the positions of the first functional layer 134a and the second functional layer 134b may be changed or reversed.

The second electrode 136 may be disposed on the functional layer 134. For example, the second electrode 136 may be disposed on the second functional layer 134b. The second electrode 136 may be disposed to entirely cover the functional layer 134. The second electrode 136 may include a conductive material having a low work function. For example, the second electrode 136 may include at least one selected from among silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and alloys thereof. The second electrode 136 may be a single layer or may include a multilayer structure.

Additional layers, such as a thin film encapsulation layer, a touch input layer, and an optical function layer may be disposed on the second electrode 136.

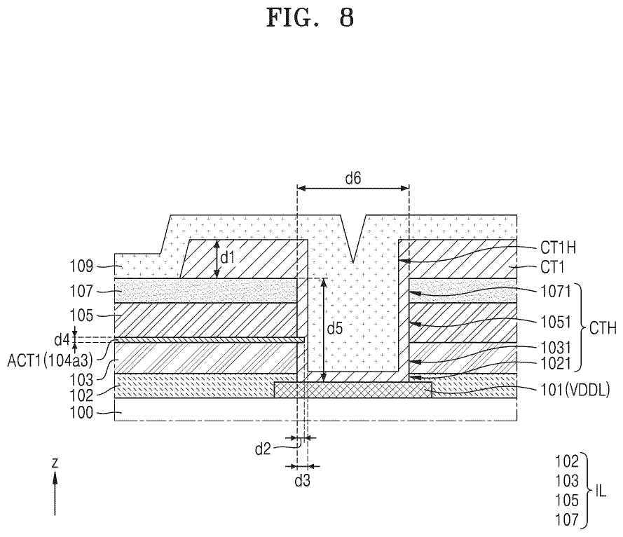

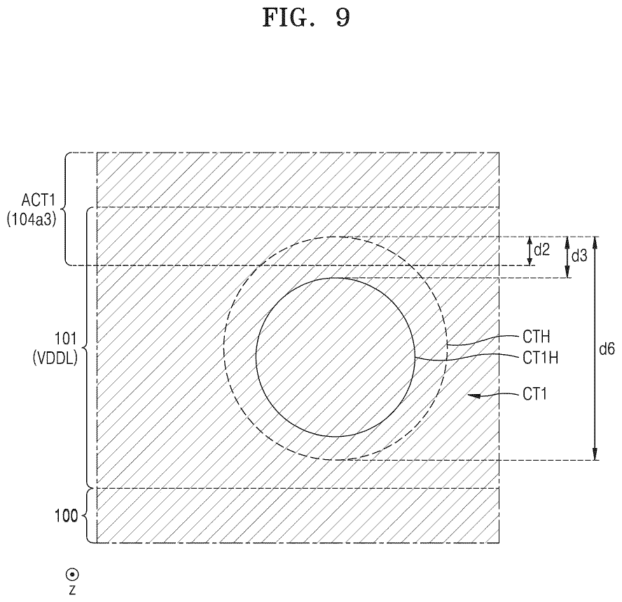

FIG. 8 is an enlarged cross-sectional view of a display panel according to an embodiment. FIG. 9 is an enlarged plan view of a display panel according to an embodiment.

Hereinafter, a connection relationship between the first contact metal CT1, the first active layer ACT1, and the first conductive layer 101 will be described in more detail. The structure and connection relationship described below are not only applicable between the first contact metal CT1, the first active layer ACT1, and the first conductive layer 101 but may also be applied between the second contact metal CT2, the second active layer ACT2, and the sixth conductive layer 114 and may also be applied between the third contact metal CT3, the fourth active layer ACT4, and the fifth conductive layer 112 (see, e.g., FIG. 7). However, for convenience of description, the first contact metal CT1, the first active layer ACT1, and the first conductive layer 101 are illustrated and described as an example below.

Referring to FIGS. 8 and 9, the first voltage line VDDL, the first insulating layer 102, the second insulating layer 103, the first active layer ACT1, the third insulating layer 105, the fourth insulating layer 107, the first contact metal CT1, and the fifth insulating layer 109 may be disposed on the substrate 100.

The first voltage line VDDL may be disposed on (or may be formed as part of) the first conductive layer 101, and a plurality of insulating layers IL (e.g., first to fourth insulating layers 102, 103, 105, and 107) may be disposed on the first conductive layer 101. In an embodiment, the first insulating layer 102 may be disposed on the first conductive layer 101 (e.g., the first voltage line VDDL), the second insulating layer 103 may be disposed on the first insulating layer 102, the third insulating layer 105 may be disposed on the second insulating layer 103, and the fourth insulating layer 107 may be disposed on the third insulating layer 105.

The first to fourth insulating layers 102, 103, 105, and 107 may each have an opening overlapping the first voltage line VDDL. In an embodiment, the first insulating layer 102 may have a first opening 1021 that overlaps the first voltage line VDDL. In an embodiment, the second insulating layer 103 may have a second opening 1031 that overlaps the first voltage line VDDL. In an embodiment, the third insulating layer 105 may have a third opening 1051 that overlaps the first voltage line VDDL. In an embodiment, the fourth insulating layer 107 may have a fourth opening 1071 that overlaps the first voltage line VDDL. The first to fourth openings 1021, 1031, 1051, and 1071 may overlap each other (e.g., may be aligned with each other) and may be spatially connected to form a contact hole (e.g., a continuous contact hole or opening) CTH. For example, a plurality of insulating layers IL may include the first to fourth insulating layers 102, 103, 105, and 107, and the contact hole CTH defined in the plurality of insulating layers IL may include first to fourth openings 1021, 1031, 1051, and 1071. In an embodiment, inner walls of the first to fourth insulating layers 102, 103, 105, and 107 defining the first to fourth openings 1021, 1031, 1051, and 1071 may be located on the same surface. In an embodiment, the first insulating layer 102 may cover an edge region (e.g., an edge) of the first voltage line VDDL, and the first to fourth openings 1021, 1031, 1051, and 1071 or the contact hole CTH may overlap a center portion of the first voltage line VDDL.

The first active layer ACT1 may be located between the second insulating layer 103 and the third insulating layer 105. A portion of the first active layer ACT1 may be located within (e.g., may extend into) the contact hole CTH. In an embodiment, a portion of the first active layer ACT1 may protrude into the third opening 1051 in the third insulating layer 105. In an embodiment, a portion of the first active layer ACT1 may protrude beyond the inner wall of the third insulating layer 105 defining the third opening 1051. In an embodiment, a portion of the first active layer ACT1 may protrude beyond the inner wall of the second insulating layer 103 defining the second opening 1031. Accordingly, an upper surface, side surface, and lower surface of a portion of the first active layer ACT1 located within the contact hole CTH may not be covered by an insulating layer.

The first contact metal CT1 may be disposed on the plurality of insulating layers IL. In an embodiment, the first contact metal CT1 may be disposed on the fourth insulating layer 107. The present disclosure is not limited to an embodiment in which the first contact metal CT1 is disposed on the fourth insulating layer 107, and the first contact metal CT1 may be disposed on any other insulating layer. A portion of the first contact metal CT1 may extend into the contact hole CTH. The first contact metal CT1 may extend into the contact hole CTH and may contact the first active layer ACT1 and the first conductive layer 101 (e.g., the first voltage line VDDL). The first active layer ACT1 and the first voltage line VDDL may be electrically connected through the first contact metal CT1.

In an embodiment, the first contact metal CT1 may have an upper portion disposed on an upper surface of the plurality of insulating layers IL, for example, the fourth insulating layer 107, a side portion disposed on an inner wall of the plurality of insulating layers IL defining the contact hole CTH, and a lower portion in direct contact with an upper surface of the first conductive layer 101 (e.g., the first voltage line VDDL). In an embodiment, the upper portion, the side portion, and the lower portion of the first contact metal CT1 may be integrally connected. In an embodiment, at least one of the upper, side, and lower surfaces of the first active layer ACT1 may be covered by the first contact metal CT1, for example, a side portion of the first contact metal CT1. For example, the upper surface, lower surface, and/or side surface of the first active layer ACT1 protruding into the contact hole CTH may be covered by the side portion of the first contact metal CT1.

In an embodiment, the first contact metal CT1 may be located along a shape (e.g., along a surface) of the contact hole CTH in the plurality of insulating layers IL, and thus, the first contact metal CT1 may have a fifth opening CT1H corresponding to a shape of the contact hole CTH. The fifth opening CT1H may overlap the contact hole CTH. The fifth opening CT1H of the first contact metal CT1 may be defined, for example, by an upper portion, a side portion, and a lower portion. The fifth insulating layer 109 may be disposed on the first contact metal CT1 and may entirely cover the first contact metal CT1. A portion of the fifth insulating layer 109 may be located along a shape of the fifth opening CT1H of the fifth opening CT1H.

In an embodiment, a thickness of a portion of the first contact metal CT1 disposed on the upper surface of the fourth insulating layer 107, for example, a thickness of the upper portion of the first contact metal CT1, may be defined as a first length d1. In an embodiment, a length of a portion of the first active layer ACT1 that protrudes beyond the inner wall of the plurality of insulating layers IL defining the contact hole CTH, for example, the inner wall of the second insulating layer 103 defining the second opening 1031 and the inner wall of the third insulating layer 105 defining the third opening 1051, may be defined as a second length d2. In an embodiment, a thickness of a portion of the first contact metal CT1 disposed on the inner wall of the plurality of insulating layers IL defining the contact hole CTH, for example, a thickness of a side portion of the first contact metal CT1, may be defined as a third length d3. In an embodiment, a thickness of the first active layer ACT1 may be defined as a fourth length d4. In an embodiment, a depth of the contact hole CTH may be defined as a fifth length d5. In an embodiment, a width of the contact hole CTH, for example, a diameter of the contact hole CTH having a circular shape when viewed in a plan view (see, e.g., FIG. 9), may be defined as a sixth length d6.

In an embodiment, the second length d2 may be in a range of about 10% to about 15% of the first length d1. For example, a length of a portion of the first active layer ACT1 protruding into the contact hole CTH may be in a range of about 10% to about 15% of a thickness of the upper portion of the first contact metal CT1.

In an embodiment, the third length d3 may be in a range of about 10% to about 15% of the first length d1. For example, a thickness of the side portion of the first contact metal CT1 may be in a range of about 10% to about 15% of a thickness of the upper portion of the first contact metal CT1.

In an embodiment, the third length d3 may be greater than or equal to the second length d2. For example, a thickness of the side portion of the first contact metal CT1 may be greater than or equal to a length of a portion of the first active layer ACT1 protruding into the contact hole CTH.

In an embodiment, the second length d2 may be less than or equal to about 150% of the fourth length d4. For example, a length of a portion of the first active layer ACT1 protruding into the contact hole CTH may be less than or equal to about 150% of a thickness of the first active layer ACT1.

In an embodiment, the fifth length d5 may be greater than or equal to the sixth length d6. For example, a depth of the contact hole CTH may be greater than or equal to a width (or a diameter) of the contact hole CTH. In other words, an aspect ratio of the contact hole CTH may be greater than or equal to 1.

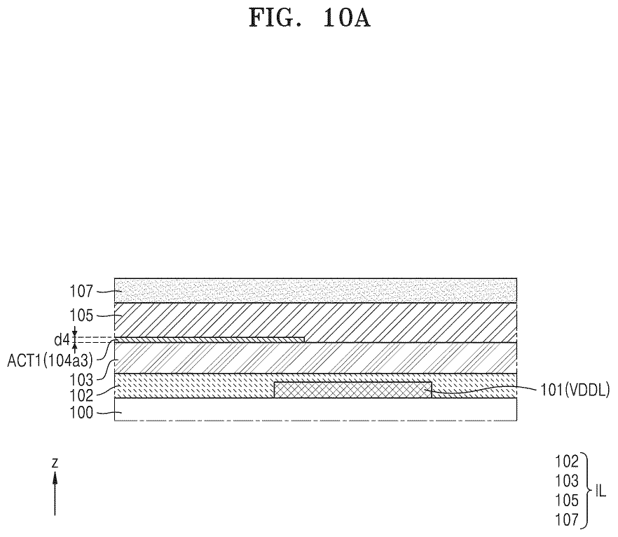

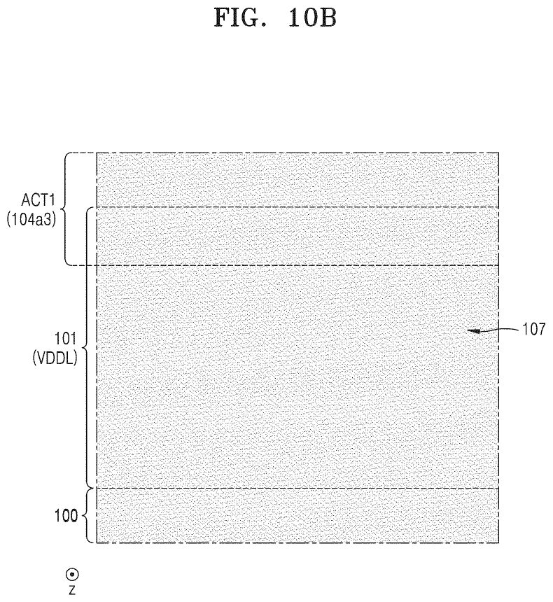

FIG. 10A is a schematic cross-sectional view of one step of a manufacturing process of a display panel according to an embodiment. FIG. 10B is a schematic plan view of one step of a manufacturing process of a display panel according to an embodiment.

Referring to FIGS. 10A and 10B, the first conductive layer 101, the first insulating layer 102, the second insulating layer 103, the first active layer ACT1, the third insulating layer 105, and the fourth insulating layer 107 may be sequentially disposed on the substrate 100. In another embodiment, the first conductive layer 101 may be disposed on the substrate 100, and the plurality of insulating layers IL and the first active layer ACT1 within the plurality of insulating layers IL may be disposed thereon. In this step of the process, openings (e.g., contact holes) may not be formed in each insulating layer. In an embodiment, the first active layer ACT1 may partially overlap the first conductive layer 101 (e.g., the first voltage line VDDL).

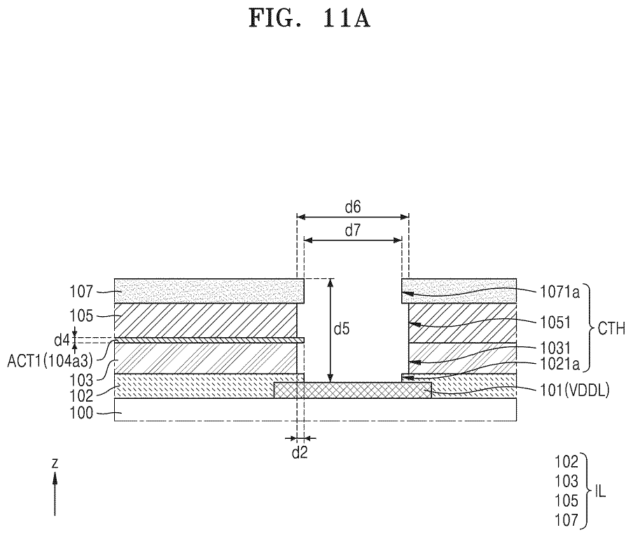

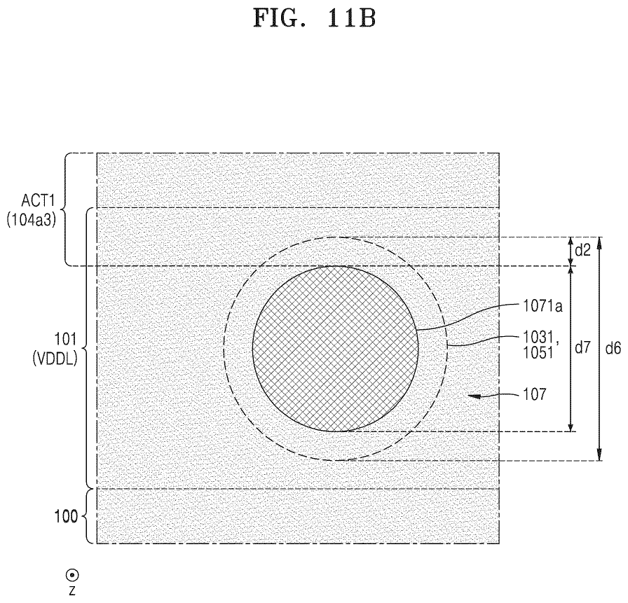

FIG. 11A is a schematic cross-sectional view of one step of a manufacturing process of a display panel according to an embodiment. FIG. 11B is a schematic plan view of one step of a manufacturing process of a display panel according to an embodiment.

Referring to FIGS. 11A and 11B, the plurality of insulating layers IL may be etched. In an embodiment, the plurality of insulating layers IL may be etched to form an opening that overlaps the first voltage line VDDL in each insulating layer. In an embodiment, the etching may include dry etching. In an embodiment, one of the plurality of insulating layers IL may include a different material than the other insulating layers. Accordingly, one insulating layer from among the plurality of insulating layers IL may have different etch selectivities from the other insulating layers. In an embodiment, the first insulating layer 102 and the fourth insulating layer 107 may include the same material, and the second insulating layer 103 and the third insulating layer 105 may include the same material. The material included in the first and fourth insulating layers 102 and 107 and the material included in the second and third insulating layers 103 and 105 may be different from each other. The etch selectivity of the first and fourth insulating layers 102 and 107 and the etch selectivity of the second and third insulating layers 103 and 105 may be different from each other. Therefore, in one etching step (or process), the shape (e.g., width) of the openings formed in the first and fourth insulating layers 102 and 107 may be different from the shape (e.g., width) of the openings formed in the second and third insulating layers 103 and 105.

In an embodiment, a 1^{st}-1 opening 1021a may be formed in the first insulating layer 102. In an embodiment, the second opening 1031 may be formed in the second insulating layer 103. In an embodiment, the third opening 1051 may be formed in the third insulating layer 105. In an embodiment, a 4^{th}-1 opening 1071a may be formed in the fourth insulating layer 107. In an embodiment, the second opening 1031 and the third opening 1051 may have the sixth length D6 as a width. In an embodiment, the 1^{st}-1 opening 1021a and the 4^{th}-1 opening 1071a may have a seventh length d7 as a width. In an embodiment, the sixth length d6 and the seventh length d7 may be different. In an embodiment, the seventh length d7 may be less than the sixth length d6.

In an embodiment, a portion of the first active layer ACT1 may protrude beyond the inner wall of the second insulating layer 103 defining the second opening 1031 and the inner wall of the third insulating layer 105 defining the third opening 1051. The protruding portion of the first active layer ACT1 may be partially exposed. For example, an upper surface, side surface, and lower surface of the protruding portion of the first active layer ACT1 may be exposed. A length of the protruding portion of the first active layer ACT1 may be defined as the second length d2. In an embodiment, the sixth length d6 may be the sum of the seventh length d7 and the second length d2. FIG. 11B illustrates an embodiment in which the first active layer ACT1 is not exposed when viewed in a plan view at the current step of the process due to the size of the 4^{th}-1 opening 1071a in the fourth insulating layer 107.

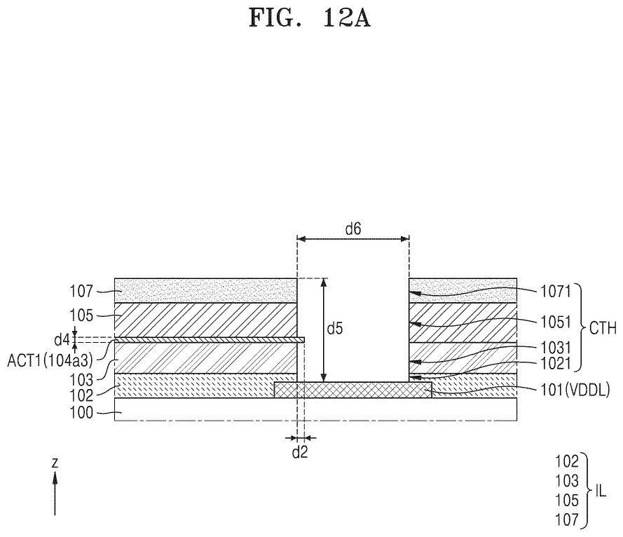

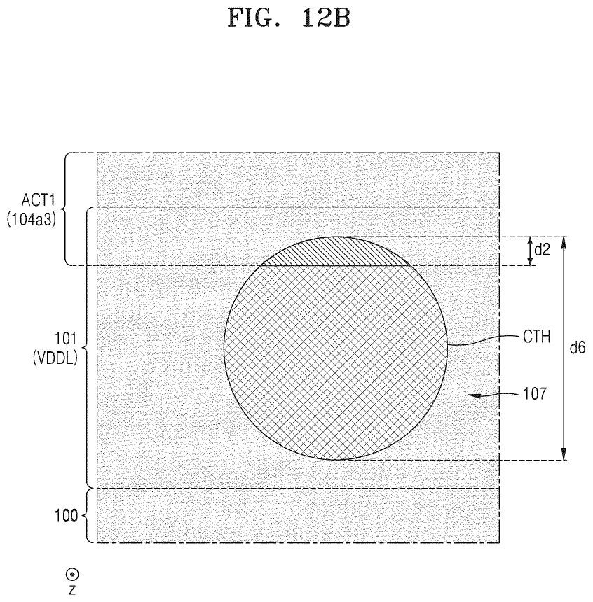

FIG. 12A is a schematic cross-sectional view of one step of a manufacturing process of a display panel according to an embodiment. FIG. 12B is a schematic plan view of one step of a manufacturing process of a display panel according to an embodiment.

Referring to FIGS. 12A and 12B, some of the plurality of insulating layers IL may be additionally processed. For example, some of the plurality of insulating layers IL (e.g., the first insulating layer 102 and the fourth insulating layer 107) may be additionally processed such that the widths of the openings defined in the plurality of insulating layers IL (e.g., the first to fourth openings 1021, 1031, 1051, and 1071) are the same. In an embodiment, the first insulating layer 102 and the fourth insulating layer 107 may be additionally (or further) etched. Referring to FIGS. 11A and 12A, the first insulating layer 102 may be additionally etched to process (e.g., expand) the 1^{st}-1 opening 1021a into the first opening 1021. The fourth insulating layer 107 may be additionally etched to process (e.g., expand) the 4^{th}-1 opening 1071a into the fourth opening 1071. The first opening 1021 and the fourth opening 1071 may have the sixth length d6 as a width. By processing the 1^{st}-1 opening 1021a and the 4^{th}-1 opening 1071a into the first opening 1021 and the fourth opening 1071, the inner walls of the first to fourth insulating layers 102, 103, 105, and 107 defining the first to fourth openings 1021, 1031, 1051, and 1071 may be located on the same surface. By processing the 1^{st}-1 opening 1021a and the 4^{th}-1 opening 1071a into the first opening 1021 and the fourth opening 1071, the contact hole CTH in the plurality of insulating layers IL may be formed. Referring to FIGS. 11B and 12B, as the 4^{th}-1 opening 1071a of the fourth insulating layer 107 expands to the fourth opening 1071, a portion of the first active layer ACT1 covered by the fourth insulating layer 107 may be exposed.

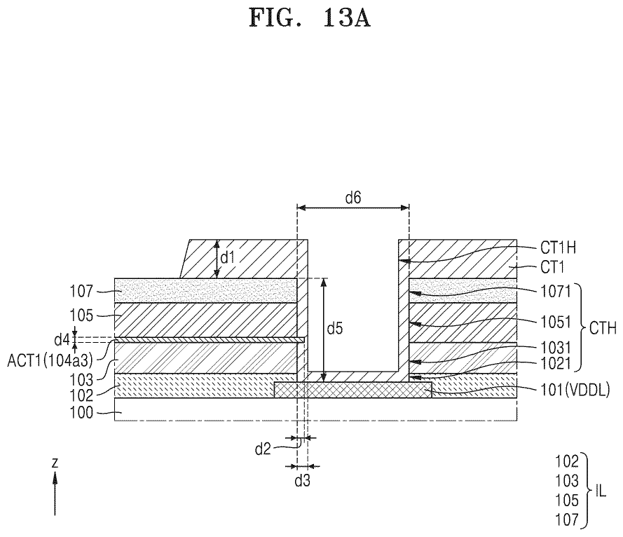

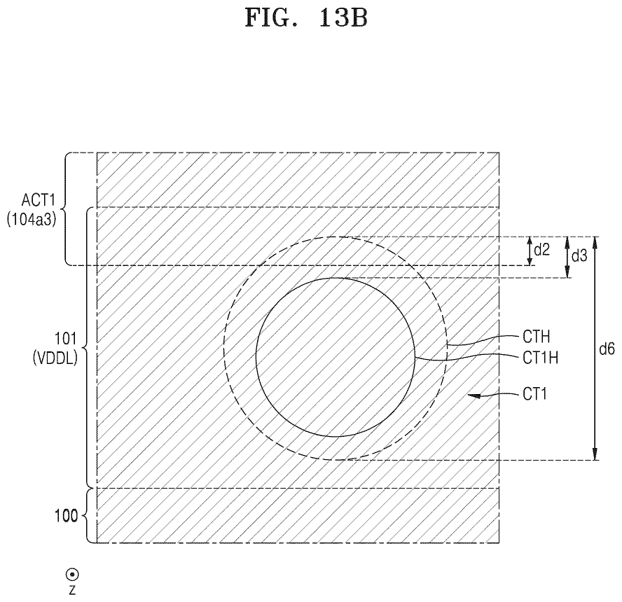

FIG. 13A is a schematic cross-sectional view of one step of a manufacturing process of a display panel according to an embodiment. FIG. 13B is a schematic plan view of one step of a manufacturing process of a display panel according to an embodiment.

Referring to FIGS. 13A and 13B, the first contact metal CT1 may be formed. The first contact metal CT1 may disposed on the fourth insulating layer 107 and a portion thereof may extend into the contact hole CTH in the plurality of insulating layers IL to be in direct contact with the first conductive layer 101 (e.g., the first voltage line VDDL) and the first active layer ACT1. The first voltage line VDDL and the first active layer ACT1 may be electrically connected through the first contact metal CT1. A relationship between the shapes and dimensions of the first contact metal CT1 and the contact hole CTH (e.g., the relationship between the first to sixth lengths d1, d2, d3, d4, d5, and d6) is described above with reference to FIGS. 8 and 9.

The present disclosure has been described with reference to embodiments shown in the drawings, but these are only examples, and those skilled in the art will understand that various modifications and equivalent other embodiments are possible therefrom. Therefore, the true technical scope of the present disclosure should be determined by the technical spirit of the appended claims and their equivalents.

According to embodiments as described above, a high-resolution display panel in which pixel circuit wirings are arranged in high density. According to an embodiment, a method of manufacturing the display panel is provided. According to an embodiment, an electronic device including the display panel is provided.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display panel comprising:
a substrate;
a conductive layer on the substrate;
a plurality of insulating layers on the conductive layer and having a contact opening overlapping the conductive layer;
a semiconductor layer within the plurality of insulating layers, the semiconductor layer having a first portion that protrudes beyond an inner wall of the plurality of insulating layers defining the contact opening to be within the contact opening; and
a contact metal on the plurality of insulating layers and extending into the contact opening to contact both the semiconductor layer and the conductive layer.

2. The display panel of claim 1, wherein the contact metal has a side portion on the inner wall of the plurality of insulating layers defining the contact opening and a lower portion integrally connected to the side portion and in direct contact with a portion of an upper surface of the conductive layer, and
wherein the semiconductor layer is in direct contact with the side portion of the contact metal.

3. The display panel of claim 2, wherein the contact metal has an upper portion that is integrally connected to the side portion thereof and is on an upper surface of the plurality of insulating layers, and
wherein a thickness of the side portion is in a range of 10% to 15% of a thickness of the upper portion.

4. The display panel of claim 3, wherein a length of the first portion of the semiconductor layer is in a range of 10% to 15% of the thickness of the upper portion of the contact metal.

5. The display panel of claim 1, wherein a length of the first portion of the semiconductor layer is 150% or less of a thickness of the semiconductor layer.

6. The display panel of claim 1, wherein inner walls of each of the plurality of insulating layers defining the contact opening are located on a same surface.

7. The display panel of claim 1, wherein a depth of the contact opening is greater than a width of the contact opening.

8. The display panel of claim 1, wherein a side surface of the first portion of the semiconductor layer is covered by the contact metal.

9. The display panel of claim 1, further comprising a light-emitting diode on the contact metal and electrically connected to the semiconductor layer.

10. A method of manufacturing a display panel, the method comprising:
disposing, on a substrate, a conductive layer, a plurality of insulating layers on the conductive layer, and a semiconductor layer within the plurality of insulating layers;
forming a contact opening overlapping the conductive layer and the semiconductor layer in the plurality of insulating layers to expose an upper surface of the conductive layer and a portion of the semiconductor layer; and
disposing a contact metal on the plurality of insulating layers and in the contact opening in the plurality of insulating layers to be in direct contact with the conductive layer and the semiconductor layer,
wherein the forming of the contact opening comprises exposing an upper surface, a side surface, and a lower surface of a first portion of the semiconductor layer overlapping the contact opening.

11. The method of claim 10, wherein the contact metal has a side portion on an inner wall of the plurality of insulating layers defining the contact opening and a lower portion integrally connected to the side portion and in direct contact with a portion of the upper surface of the conductive layer, and
wherein the semiconductor layer is in direct contact with the side portion of the contact metal.

12. The method of claim 11, wherein the contact metal has an upper portion that is integrally connected to the side portion and is on an upper surface of the plurality of insulating layers, and
wherein a thickness of the side portion is in a range of 10% to 15% of a thickness of the upper portion.

13. The method of claim 12, wherein the first portion of the semiconductor layer protrudes from the inner wall of the plurality of insulating layers defining the contact opening, and
wherein a length of the first portion measured in a direction from the inner wall of the plurality of insulating layers toward the contact opening is in a range of 10% to 15% of the thickness of the upper portion of the contact metal.

14. The method of claim 13, wherein the length of the first portion, measured in the direction from the inner wall of the plurality of insulating layers toward the contact opening, is 150% or less of a thickness of the semiconductor layer.

15. The method of claim 10, wherein some of the plurality of insulating layers comprise materials having different etch selectivities, and
wherein the forming of the contact opening in the plurality of insulating layers comprises etching the plurality of insulating layers such that a width of an opening in one of the plurality of insulating layers is different from a width of an opening in another of the plurality of insulating layers.

16. The method of claim 15, wherein the forming of the contact opening in the plurality of insulating layers comprises additionally processing some of the plurality of insulating layers such that widths of the openings in the plurality of insulating layers are same.

17. The method of claim 10, wherein a depth of the contact opening is greater than a width of the contact opening.

18. The method of claim 10, wherein the contact metal covers a side surface of the first portion of the semiconductor layer.

19. An electronic device comprising:
a display panel; and
a processor configured to drive the display panel,
wherein the display panel comprises:
a substrate;
a conductive layer on the substrate;
a plurality of insulating layers on the conductive layer and having a contact opening overlapping the conductive layer;
a semiconductor layer within the plurality of insulating layers, the semiconductor layer having a first portion that protrudes beyond an inner wall of the plurality of insulating layers defining the contact opening to be within the contact opening; and
a contact metal on the plurality of insulating layers and extending into the contact opening to contact both the semiconductor layer and the conductive layer.

20. The electronic device of claim 19, wherein the contact metal has a side portion on an inner wall of the plurality of insulating layers defining the contact opening and in direct contact with the semiconductor layer, a lower portion integrally connected to the side portion and in direct contact with a portion of an upper surface of the conductive layer, and an upper portion integrally connected to the side portion and on an upper surface of the plurality of insulating layers, and
wherein a thickness of the side portion is in a range of 10% to 15% of a thickness of the upper portion.
